(19) United States
(12) Patent Application Publication
(10) Pub. No.: US 2020/0251159 A1
(43) Pub. Date: Aug. 6, 2020

(54) STACKED MEMORY DEVICE WITH END TO END DATA BUS INVERSION

(71) Applicant: Intel Corporation, Santa Clara, CA (US)

(72) Inventors: Narasimha Lanka, Dublin, CA (US); Kuljit Bains, Olympia, WA (US); Lakshmipriya Seshan, Sunnyvale, CA (US)

(73) Assignee: Intel Corporation, Santa Clara, CA (US)

(21) Appl. No.: 16/854,280

(22) Filed: Apr. 21, 2020

(51) Int. Cl. G11C 11/4063; H01L 27/108; H01L 27/06; H01L 23/538; G11C 5/06

(52) U.S. Cl. CPC G11C 11/4063; H01L 27/10805; G11C 5/06; H01L 23/5384; H01L 27/0688

(57) ABSTRACT

An embodiment of a memory apparatus may include a memory core, a plurality of through-silicon vias (TSVs), and data bus inversion logic coupled between the memory core and the TSVs to encode and decode a data signal on a signal path through the TSVs in accordance with a data bus inversion of the data signal. Other embodiments are disclosed and claimed.

### BACKGROUND

Standards for a high bandwidth memory (HBM) dynamic random access memory (DRAM) interface are published by JEDEC (www.jedec.org). Updates to these standards include HBM2 and HMB2E. HBM technology provides higher bandwidth at lower power consumption as compared to some other memory technologies. HBM technology may include stacks of memory dice and a much wider memory bus as compared to some other memory technologies.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a block diagram of an example of a memory apparatus according to an embodiment;

FIG. 2 is a block diagram of an example of an electronic apparatus according to an embodiment;

FIGS. 3A and 3B are bar graphs of examples of number of lanes switching versus total occurrences according to embodiments;

FIG. 4 is an illustrative timing diagram of an example of data bus inversion according to an embodiment;

FIG. 5 is an illustrative timing diagram of another example of data bus inversion with internal data bus inversion according to an embodiment;

FIG. 6 is a perspective, block diagram view of an example of a memory stack device according to an embodiment;

FIGS. 7A to 7B are front view and top view block diagrams, respectively, of an example of an electronic apparatus according to an embodiment;

FIG. 8 is a block diagram of another example of a memory apparatus according to an embodiment;

FIG. 9 is a block diagram of an example of a computing system according to an embodiment.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

While the following description sets forth various implementations that may be manifested in architectures such as system-on-a-chip (SoC) architectures for example, implementation of the techniques and/or arrangements described herein are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, etc., may implement the techniques and/or arrangements described herein. Further, while the following description may set forth numerous specific details such as logic implementations, types and interrelationships of system components, logic partitioning/integration choices, etc., claimed subject matter may be practiced without such specific details. In other instances, some material such as, for example, control structures and full software instruction sequences, may not be shown in detail in order not to obscure the material disclosed herein.

The material disclosed herein may be implemented in hardware, firmware, software, or any combination thereof. The material disclosed herein may also be implemented as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

References in the specification to “one implementation”, “an implementation”, “an example implementation”, etc., indicate that the implementation described may include a particular feature, structure, or characteristic, but every embodiment may not necessarily include the particular feature, structure, or characteristic. Moreover, such phrases are not necessarily referring to the same implementation. Further, when a particular feature, structure, or characteristic is described in connection with an embodiment, it is submitted that it is within the knowledge of one skilled in the art to effect such feature, structure, or characteristic in connection with other implementations whether or not explicitly described herein.

Various embodiments described herein may include a memory component and/or an interface to a memory component. Such memory components may include volatile and/or nonvolatile (NV) memory. Volatile memory may be a storage medium that requires power to maintain the state of data stored by the medium. Non-limiting examples of volatile memory may include various types of RAM, such as DRAM or static RAM (SRAM). One particular type of DRAM that may be used in a memory module is synchronous dynamic RAM (SDRAM). In particular embodiments, DRAM of a memory component may comply with a standard promulgated by Joint Electron Device Engineering Council (JEDEC), such as JESD79F for double data rate (DDR) SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4 (these standards are available at jedec.org). Such standards (and similar standards) may be referred to as DDR-based standards and communication interfaces of the storage devices that implement such standards may be referred to as DDR-based interfaces.

NV memory (NVM) may be a storage medium that does not require power to maintain the state of data stored by the medium. In one embodiment, the memory device may include a block addressable memory device, such as those based on NAND or NOR technologies. A memory device may also include future generation nonvolatile devices, such as a three dimensional (3D) crosspoint memory device, or other byte addressable write-in-place nonvolatile memory devices. In one embodiment, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor RAM (FeTRAM), anti-ferroelectric memory, magnetoresistive RAM (MRAM) memory that incorporates memristor technology, resistive memory including the metal oxide base, the oxygen vacancy base and the conductive bridge RAM (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In particular embodiments, a memory component with non-volatile memory may comply with one or more standards promulgated by the JEDEC, such as JESD218, JESD219, JESD220-1, JESD223B, JESD223-1, or other suitable standard (the JEDEC standards cited herein are available at jedec.org).

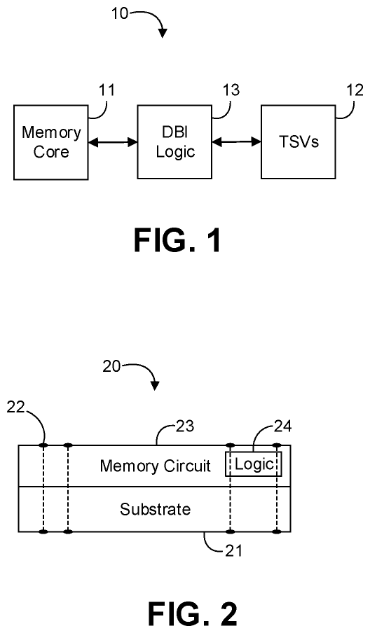

With reference to FIG. 1, an embodiment of a memory apparatus 10 may include a memory core 11, a plurality of through-silicon vias (TSVs) 12, and data bus inversion (DBI) logic 13 coupled between the memory core 11 and the TSVs 12. The DBI logic 13 may be configured to encode and decode a data signal on a signal path through the TSVs 12 in accordance with a data bus inversion of the data signal. In some embodiments, the DBI logic 13 may be configured to extend the data bus inversion of the data signal from a memory controller to a physical layer of the memory apparatus, and/or to extend the data bus inversion from a memory controller to the memory core 11.

In some embodiments, the DBI logic 13 may be further configured to arrange bits of the data signal non-sequentially among the TSVs 12 in accordance with the data bus inversion of the data signal. For example, the DBI logic 13 may include a multi-entry first-in-first-out (FIFO) buffer to arrange the bits of the data signal non-sequentially (e.g., a two entry FIFO). In some embodiments, the memory core 11 may be associated with a plurality of ranks, and the DBI logic 13 may be further configured to keep track of previous read cycles for consecutive read operations to different ranks of the plurality of ranks, and to keep track of data sent from an inactive rank of the plurality of ranks.

Embodiments of each of the above memory core 11, TSVs 12, DBI logic 13, and other system components may be implemented with any suitable memory technology, including hardware, software, or any suitable combination thereof. For example, hardware implementations may include configurable logic such as, for example, programmable logic arrays (PLAs), field programmable gate arrays (FPGAs), complex programmable logic devices (CPLDs), or fixed-functionality logic hardware using circuit technology such as, for example, application specific integrated circuit (ASIC), complementary metal oxide semiconductor (CMOS) or transistor-transistor logic (TTL) technology, or any combination thereof.

In some embodiments, the memory components may be located in, or co-located with, various other components, including a controller (e.g., on a same die). Embodiments of a suitable controller may include a general purpose controller, a special purpose controller, a memory controller, a storage controller, a micro-controller, a general purpose processor, a special purpose processor, a central processor unit (CPU), an execution unit, etc. Alternatively, or additionally, all or portions of the controller may be implemented in one or more modules as a set of logic instructions stored in a machine- or computer-readable storage medium such as random access memory (RAM), read only memory (ROM), programmable ROM (PROM), firmware, flash memory, etc., to be executed by a processor or computing device. For example, computer program code to carry out the operations of the components may be written in any combination of one or more operating system (OS) applicable/appropriate programming languages, including an object-oriented programming language such as PYTHON, PERL, JAVA, SMALLTALK, C++, C# or the like and conventional procedural programming languages, such as the “C” programming language or similar programming languages.

Turning now to FIG. 2, an embodiment of an electronic apparatus 20 may include a silicon substrate 21, a plurality of vias 22 disposed completely through the silicon substrate 21 (e.g., TSVs), and a memory circuit 23 coupled to the silicon substrate 21 and the plurality of vias 22. The memory circuit 23 may include logic 24 to encode and decode a data signal on a signal path through the plurality of vias 22 in accordance with a data bus inversion of the data signal. In some embodiments, the logic 24 may be configured to extend the data bus inversion of the data signal from a memory controller to a physical layer of the memory circuit 23, and/or to extend the data bus inversion from a memory controller to a memory core of the memory circuit 23.

In some embodiments, the logic 24 may be further configured to arrange bits of the data signal non-sequentially among the plurality of vias 22 in accordance with the data bus inversion of the data signal. For example, the logic 24 may include a multi-entry FIFO buffer to arrange the bits of the data signal non-sequentially (e.g. a two entry FIFO). In some embodiments, the memory circuit 23 may be associated with a plurality of ranks, and the logic 24 may be further configured to keep track of previous read cycles for consecutive read operations to different ranks of the plurality of ranks, and to keep track of data sent from an inactive rank of the plurality of ranks.

In any of the embodiments herein, the memory circuit 23 may comprise RAM, such as DRAM. In some memory devices, multiple embodiments of the apparatus 20 may be coupled to each other utilizing a plurality of through-silicon-vias (TSVs), as may be utilized in various HBM technologies, for example. Embodiments of the silicon substrate 21, vias 22, memory circuit 23, and logic 24 may be fabricated utilizing any suitable silicon/memory fabrication techniques.

For example, the electronic apparatus 10 may be implemented on a semiconductor apparatus which includes the silicon substrate 21, with the memory circuit 23 coupled to the silicon substrate 21. In some embodiments, the memory circuit 23 may be at least partly implemented in one or more of memory components on the silicon substrate 21. For example, the memory circuit 23 may include a transistor array and/or other integrated circuit components coupled to the silicon substrate 21 with transistor channel regions that are positioned within the silicon substrate 21. The interface between the memory circuit 23 and the silicon substrate 21 may not be an abrupt junction. The memory circuit 23 may also be considered to include an epitaxial layer that is grown on an initial wafer of the silicon substrate 21.

Some embodiments may advantageously provide technology for end to end DBI to enable power savings in stacked memory devices. DBI technology may be utilized used in various parallel input/output (IO) circuits to limit the count of simultaneous lane switching to reduce power and simultaneous switching operation (SSO) noise. In stacked memory devices, such as HBM devices, DBI encoding and decoding may conventionally be performed in a logic base die while the TSV path to the memory cores is conventionally an un-encoded transmission. A problem with the conventional arrangements is that the un-encoded transmission to the memory cores increases power consumption, voltage droop, and SSO noise. Advantageously, some embodiments include technology to extend the DBI all the way to the memory cores, thereby significantly reducing one or more of power consumption, voltage droop, and SSO noise.

As speeds of HBM devices increase, the data on the DQ bus may be parallelized through the TSV path (e.g., 1-DQ:2-TSV in HBM2; 1-DQ:4-TSV in HBM3, and so on) to limit the core clock speed increase. Some embodiments may re-arrange the burstlength (BL) bits (e.g., BL0-BL7) to extend the DBI encoding from the memory controller to the HBM device memory cores through the TSV signal path.

The heat generated in an HBM device may be directly proportional to its power consumption. Because the HBM device may be on the same package as a SoC device, the heat generated by the HBM device directly translates to the cooling solution. Device power in some HBM devices may be over 20 Watts. Furthermore, HBM device performance may be limited by the robustness of the power delivery solution. Significant package resources may be required to deliver the required power delivery performance, which may depend on the instantaneous current consumption. Some embodiments may advantageous reduce power consumption and/or reduce switching currents to alleviate the package power delivery constraints.

Approximately 40% of the total power consumption may be for data transmission though TSVs. Some embodiments may provide DBI technology to reduce the average toggling and to reduce average power consumption. For an 8-bit data per DBI encoding, the average cycle-to-cycle toggle count may be reduced by about 20% (e.g., advantageously providing about 1.6 Watt power savings on a 20 Watt HBM device. The transient current (ICC(t)) may be directly proportional to a number of lanes switching every cycle. Some embodiments may provide DBI technology to limit the count to half the bits/DBI, thereby reducing ICC(t) in the memory core region and making the power delivery more robust. Some embodiments may be independently applied for the path from a SoC memory controller and the SoC physical layer (PHY), and/or the path from the SoC PHY to the HBM device memory cores. In some embodiment, more advantages are realized by applying DBI technology from the memory controller to the HBM device memory cores.

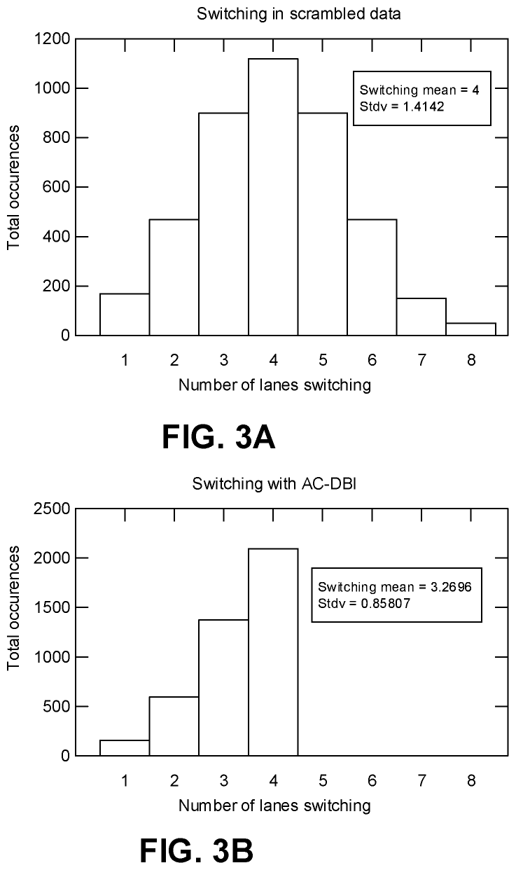

With reference to FIGS. 3A and 3B, example bar graphs show an impact of alternating current (AC)-DBI. An encoding of 8-bits/DBI is shown with a total run length of 2\hat{ }12 bits. The graphs show histograms of the count of lanes switching from cycle-cycle. A scrambled data without AC-DBI averages to 4 lanes switching from cycle to cycle (e.g., see FIG. 3A). When AC-DBI is applied, the average goes down asymptotically to about 3.21 lanes (e.g., see FIG. 3B), including a DBI lane. Advantageously, applying DBI reduces average switching by about 20%.

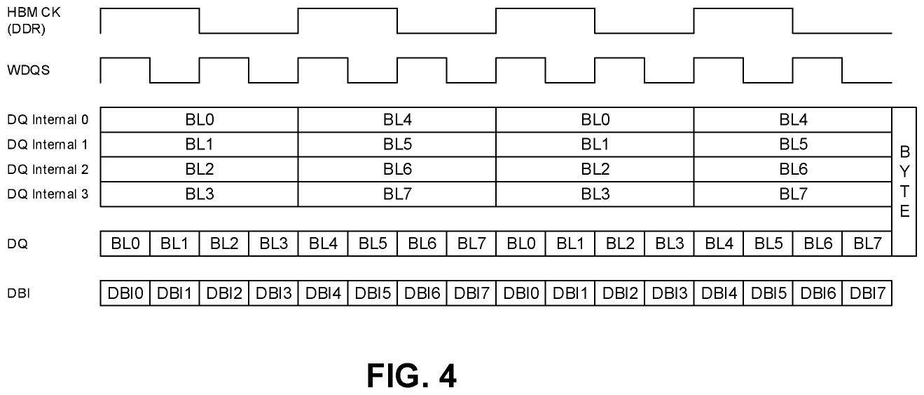

With reference to FIG. 4, an example sequential bit arrangement and timing diagram for a burst length of 8 is shown for a HBM device architecture having a 1:4 IO to internal bus interleaving ratio. The illustrated arrangement may reduce latency but precludes extending the same DBI encoding to an internal TSV path. For example, DBI1 bit encoded the switching activity between BL0 and BL1 but DQ internal 0 transmits BL0 followed by BL4.

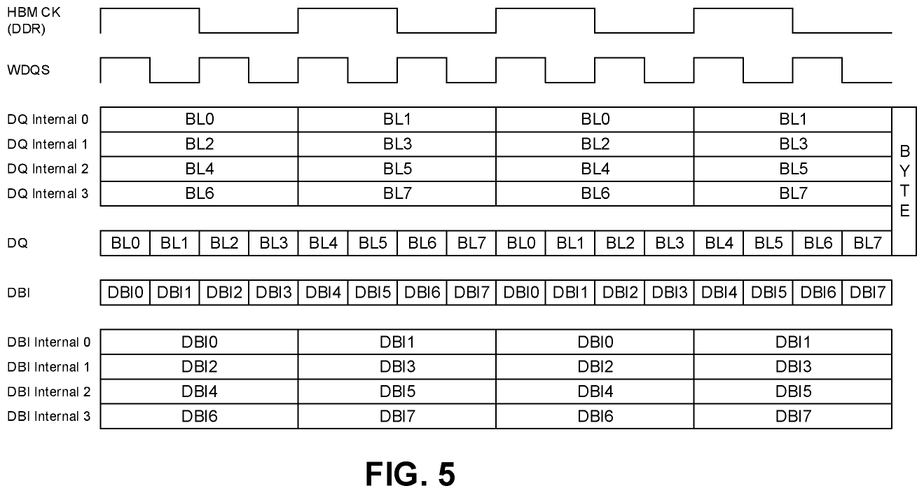

With reference to FIG. 5, an example non-sequential bit arrangement and timing diagram for a burst length of 8 is shown for a HBM device architecture having a 1:4 IO to internal bus interleaving ratio. By organizing the bits as shown and adding an internal DBI path, the same DBI encoding is advantageously extended from the memory controller through the SoC PHY and all the way to the memory cores (e.g., through the base logic die and along the TSV path). In some embodiments, the additional DBI internal path may add about 12% additional TSVs. In some embodiments, a two entry FIFO may be utilized to re-arrange the initial IO bit arrangement to the DBI bit arrangement.

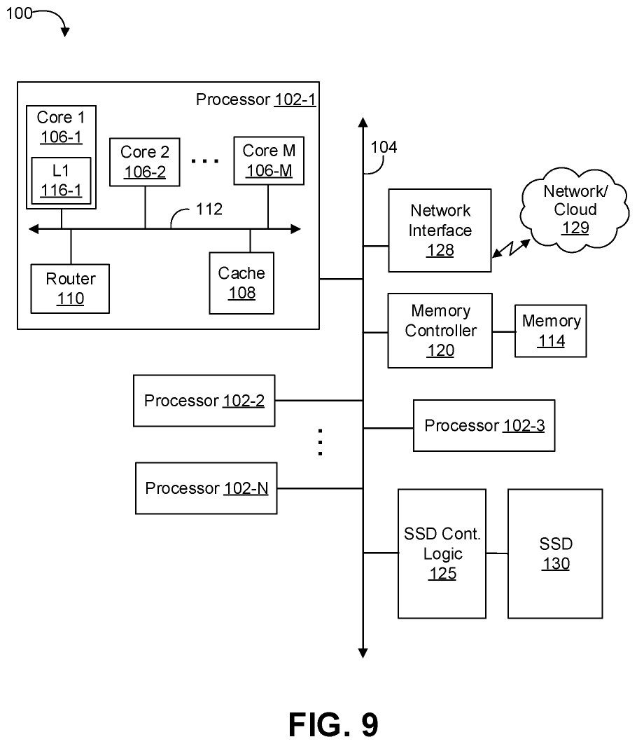

In some embodiments, the HBM device may include a multi-rank system with the same channel distributed across different ranks. The memory controller or the DBI logic may keep track of the previous cycle for consecutive READs to different ranks. Because the TSVs may be connected to the channel for all ranks (e.g., see FIG. 9), the DBI logic in the inactive ranks may keep track of the data sent. Additional timing may be available between rank switches which will allow the device to precondition the bus and ensure proper DBI operation.

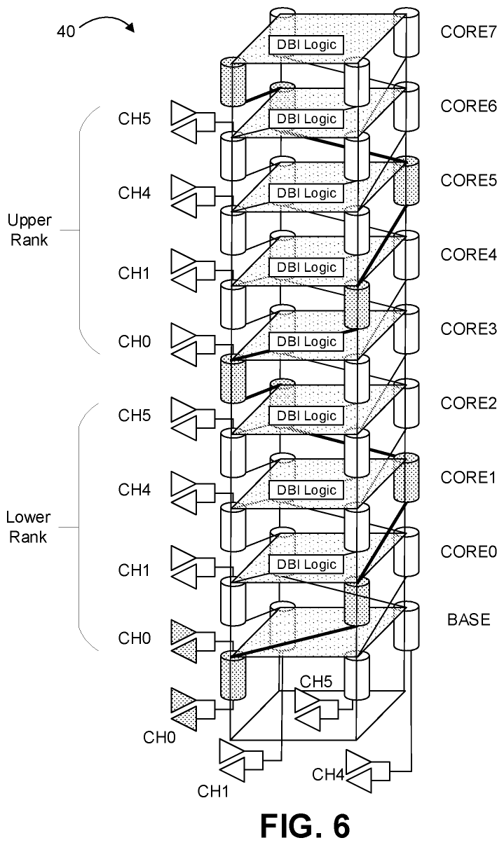

With reference to FIG. 6, an embodiment of a memory stack device 40 may include a base logic device and a stack of eight (8) memory devices CORE0 through CORE7, coupled as shown. Each of the memory devices may include DBI logic as described herein. Those skilled in the art will appreciate that the illustrated arrangement is one example of a suitable TSV arrangement. Any suitable number of memory cores together with any suitable TSV arrangement may be utilized in other embodiments, together with suitable DBI logic for each of the memory cores.

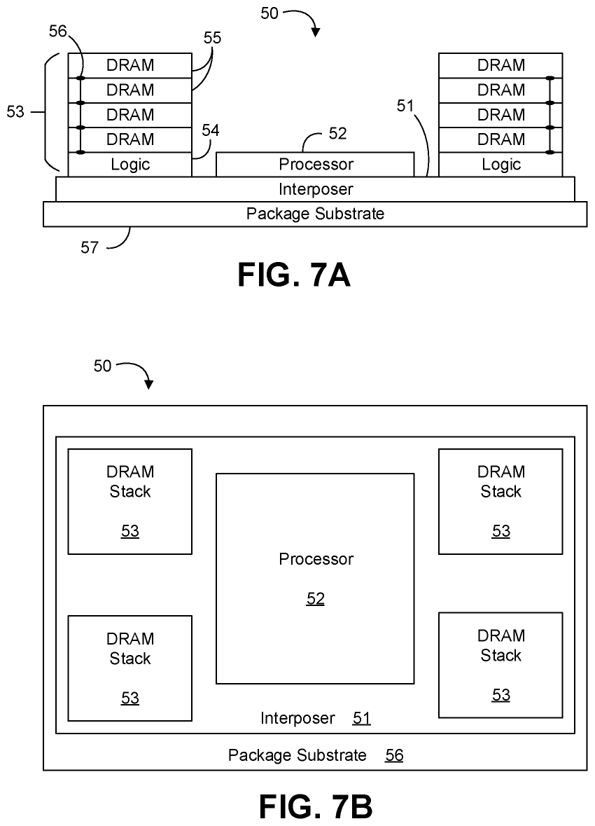

With reference to FIGS. 7A to 7B, an embodiment of an electronic apparatus 50 may include an interposer 51, a processor 52 coupled to the interposer 51, and at least one memory stack device 53 (e.g., a DRAM stack) coupled to the interposer 51 and communicatively coupled to the processor 52 through the interposer 51. The at least one memory stack device 53 may include a stack of dice including at least one logic die 54 and at least two WP memory dice 55 (e.g., DRAM). An inter-die connection for the memory dice 55 and/or logic die 54 may be made with through silicon vias (TSVs) 56, for example. The at least two memory dice 55 may each comprise DBI logic (e.g., as described herein). In some embodiments, the apparatus 50 may further include a package substrate 57 coupled to the interposer 51. For example, the package substrate 57 may include a SoC package or a printed circuit board such as graphics board, a HPC board, etc.

In some embodiments, the DBI logic integrated on each memory dice 55 may be configured to encode and decode a data signal on a signal path through the TSVs 56 in accordance with a data bus inversion of the data signal. For example, the DBI logic may be configured to extend the data bus inversion from the processor 52 to the at least two memory dice 55 (e.g., or from the processor 52 to the SOC PHY, or from the SOC PHY to the memory dice 55). In some embodiments, the DBI logic may be further configured to arrange bits of the data signal non-sequentially among the TSVs 56 in accordance with the data bus inversion of the data signal. For example, the DBI logic may include a multi-entry FIFO buffer to arrange the bits of the data signal non-sequentially. In some embodiments, the at least one memory stack device 53 may be associated with a plurality of ranks, and the DBI logic may be configured to keep track of previous read cycles for consecutive read operations to different ranks of the plurality of ranks, and/or to keep track of data sent from an inactive rank of the plurality of ranks.

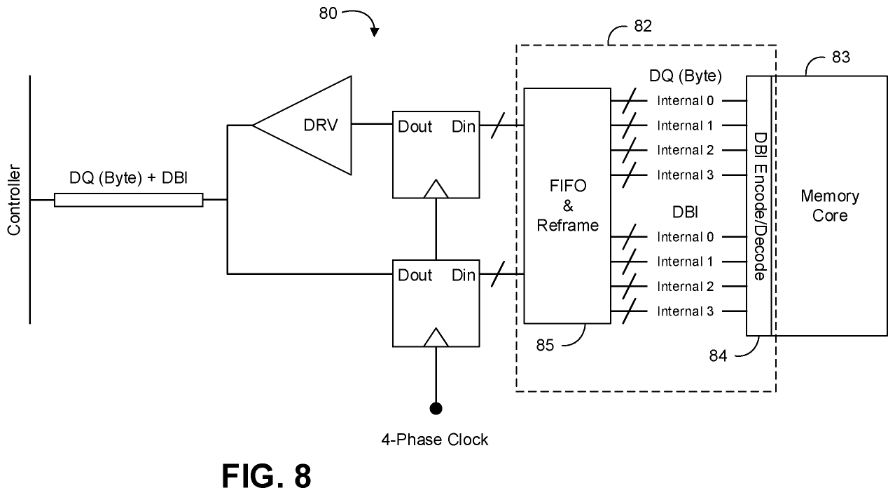

With reference to FIG. 8, an embodiment of a memory apparatus 80 may include DBI logic 82 at least partially integrated with a memory core 83. The DBI logic 82 may include DBI encode/decode logic 84 and a two-entry FIFO 85 to non-sequentially arrange bits among an internal DBI signal path. For example, the internal DBI signal path may be provided by TSVs in a memory stack device. The DBI logic 82 may extend data bus inversion from a controller all the way to the memory core 83.

During operation, a DBI encoded DQ byte with a DBI bit is sent over the interface between controller and the memory apparatus 80. During WRITES, the memory apparatus 80 may receive the data using a divided four phase clock. The FIFO 85 is configured to receive two cycles of data and reframe it as shown. The DBI bit is also deserialized along with DQ and sent over the internal bus (TSV) to the memory core 83 where the DBI decoding is performed by the DBI encode/decode logic 84. The opposite happens during READs. Data is DBI encoded in the memory core by the DBI encode/decode logic 84 and sent over the internal bus. The data is reframed in the FIFO 85 and serialized to be sent over the interface between the memory apparatus 80 and the controller.

The technology discussed herein may be provided in various computing systems (e.g., including a non-mobile computing device such as a desktop, workstation, server, rack system, etc., a mobile computing device such as a smartphone, tablet, Ultra-Mobile Personal Computer (UMPC), laptop computer, ULTRABOOK computing device, smart watch, smart glasses, smart bracelet, etc., and/or a client/edge device such as an Internet-of-Things (IoT) device (e.g., a sensor, a camera, etc.)).

Turning now to FIG. 9, an embodiment of a computing system 100 may include one or more processors 102-1 through 102-N (generally referred to herein as “processors 102” or “processor 102”). The processors 102 may communicate via an interconnection or bus 104. Each processor 102 may include various components some of which are only discussed with reference to processor 102-1 for clarity. Accordingly, each of the remaining processors 102-2 through 102-N may include the same or similar components discussed with reference to the processor 102-1.

In some embodiments, the processor 102-1 may include one or more processor cores 106-1 through 106-M (referred to herein as “cores 106,” or more generally as “core 106”), a cache 108 (which may be a shared cache or a private cache in various embodiments), and/or a router 110. The processor cores 106 may be implemented on a single integrated circuit (IC) chip. Moreover, the chip may include one or more shared and/or private caches (such as cache 108), buses or interconnections (such as a bus or interconnection 112), memory controllers, or other components.

In some embodiments, the router 110 may be used to communicate between various components of the processor 102-1 and/or system 100. Moreover, the processor 102-1 may include more than one router 110. Furthermore, the multitude of routers 110 may be in communication to enable data routing between various components inside or outside of the processor 102-1.

The cache 108 may store data (e.g., including instructions) that is utilized by one or more components of the processor 102-1, such as the cores 106. For example, the cache 108 may locally cache data stored in a memory 114 for faster access by the components of the processor 102. As shown in FIG. 9, the memory 114 may be in communication with the processors 102 via the interconnection 104. In some embodiments, the cache 108 (that may be shared) may have various levels, for example, the cache 108 may be a mid-level cache and/or a last-level cache (LLC). Also, each of the cores 106 may include a level 1 (L1) cache (116-1) (generally referred to herein as “L1 cache 116”). Various components of the processor 102-1 may communicate with the cache 108 directly, through a bus (e.g., the bus 112), and/or a memory controller or hub.

As shown in FIG. 9, memory 114 may be coupled to other components of system 100 through a memory controller 120. Memory 114 may include volatile memory and may be interchangeably referred to as main memory. Even though the memory controller 120 is shown to be coupled between the interconnection 104 and the memory 114, the memory controller 120 may be located elsewhere in system 100. For example, memory controller 120 or portions of it may be provided within one of the processors 102 in some embodiments.

The system 100 may communicate with other devices/systems/networks via a network interface 128 (e.g., which is in communication with a computer network and/or the cloud 129 via a wired or wireless interface). For example, the network interface 128 may include an antenna (not shown) to wirelessly (e.g., via an Institute of Electrical and Electronics Engineers (IEEE) 802.11 interface (including IEEE 802.11a/b/g/n/ac, etc.), cellular interface, 3G, 4G, LTE, BLUETOOTH, etc.) communicate with the network/cloud 129.

System 100 may also include a storage device such as a SSD device 130 coupled to the interconnect 104 via SSD controller logic 125. Hence, logic 125 may control access by various components of system 100 to the SSD device 130. Furthermore, even though logic 125 is shown to be directly coupled to the interconnection 104 in FIG. 9, logic 125 can alternatively communicate via a storage bus/interconnect (such as the SATA (Serial Advanced Technology Attachment) bus, Peripheral Component Interconnect (PCI) (or PCI EXPRESS (PCIe) interface), NVM EXPRESS (NVMe), etc.) with one or more other components of system 100 (for example where the storage bus is coupled to interconnect 104 via some other logic like a bus bridge, chipset, etc.) Additionally, logic 125 may be incorporated into memory controller logic or provided on a same integrated circuit (IC) device in various embodiments (e.g., on the same circuit board device as the SSD device 130 or in the same enclosure as the SSD device 130).

Furthermore, logic 125 and/or SSD device 130 may be coupled to one or more sensors (not shown) to receive information (e.g., in the form of one or more bits or signals) to indicate the status of or values detected by the one or more sensors. These sensor(s) may be provided proximate to components of system 100 (or other computing systems discussed herein), including the cores 106, interconnections 104 or 112, components outside of the processor 102, SSD device 130, SSD bus, SATA bus, logic 125, etc., to sense variations in various factors affecting power/thermal behavior of the system/platform, such as temperature, operating frequency, operating voltage, power consumption, and/or inter-core communication activity, etc.

Advantageously, the memory 114, or other memory communicatively coupled to the processors 102, may include technology to implement one or more aspects of the apparatus 10 (FIG. 1), the apparatus 20 (FIG. 2), the memory stack device 40 (FIG. 6), the apparatus 50 (FIGS. 7A and 7B), the apparatus 80 (FIG. 8), and/or any of the features discussed herein. For example, the memory 114 may include an embodiment of a HBM compatible DRAM device with an internal DBI path with one or more of the features discussed herein (e.g., memory cores with DBI logic, extra TSVs for the internal DBI path, etc.).

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrase “one or more of A, B, and C” and the phrase “one or more of A, B, or C” both may mean A; B; C; A and B; A and C; B and C; or A, B and C. Various components of the systems described herein may be implemented in software, firmware, and/or hardware and/or any combination thereof. For example, various components of the systems or devices discussed herein may be provided, at least in part, by hardware of a computing SoC such as may be found in a computing system such as, for example, a smart phone. Those skilled in the art may recognize that systems described herein may include additional components that have not been depicted in the corresponding figures. For example, the systems discussed herein may include additional components such as bit stream multiplexer or de-multiplexer modules and the like that have not been depicted in the interest of clarity.

While implementation of the example processes discussed herein may include the undertaking of all operations shown in the order illustrated, the present disclosure is not limited in this regard and, in various examples, implementation of the example processes herein may include only a subset of the operations shown, operations performed in a different order than illustrated, or additional operations.

In addition, any one or more of the operations discussed herein may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more graphics processing unit(s) or processor core(s) may undertake one or more of the blocks of the example processes herein in response to program code and/or instructions or instruction sets conveyed to the processor by one or more machine-readable media. In general, a machine-readable medium may convey software in the form of program code and/or instructions or instruction sets that may cause any of the devices and/or systems described herein to implement at least portions of the operations discussed herein and/or any portions the devices, systems, or any module or component as discussed herein.

As used in any implementation described herein, the term “module” refers to any combination of software logic, firmware logic, hardware logic, and/or circuitry configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, fixed function circuitry, execution unit circuitry, and/or firmware that stores instructions executed by programmable circuitry. The modules may, collectively or individually, be embodied as circuitry that forms part of a larger system, for example, an integrated circuit (IC), system on-chip (SoC), and so forth.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the embodiments are not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An electronic apparatus, comprising:
a silicon substrate;
a plurality of vias disposed completely through the silicon substrate; and
a memory circuit coupled to the silicon substrate and the plurality of vias, the memory circuit including logic to:
encode and decode a data signal on a signal path through the plurality of vias in accordance with a data bus inversion of the data signal.

2. The apparatus of claim 1, wherein the logic is further to:
extend the data bus inversion of the data signal from a memory controller to a physical layer of the memory circuit.

3. The apparatus of claim 1, wherein the logic is further to:
extend the data bus inversion from a memory controller to a memory core of the memory circuit.

4. The apparatus of claim 1, wherein the logic is further to:
arrange bits of the data signal non-sequentially among the plurality of vias in accordance with the data bus inversion of the data signal.

5. The apparatus of claim 4, wherein the logic comprises:
a multi-entry first-in-first-out buffer to arrange the bits of the data signal non-sequentially.

6. The apparatus of claim 1, wherein the memory circuit is associated with a plurality of ranks, and wherein the logic is further to:
keep track of previous read cycles for consecutive read operations to different ranks of the plurality of ranks.

7. The apparatus of claim 6, wherein the logic is further to:
keep track of data sent from an inactive rank of the plurality of ranks.

8. A memory apparatus, comprising:
a memory core;
a plurality of through-silicon vias (TSVs); and
data bus inversion logic coupled between the memory core and the TSVs to:
encode and decode a data signal on a signal path through the TSVs in accordance with a data bus inversion of the data signal.

9. The apparatus of claim 8, wherein the data bus inversion logic is further to:
extend the data bus inversion of the data signal from a memory controller to a physical layer of the memory apparatus.

10. The apparatus of claim 8, wherein the data bus inversion logic is further to:
extend the data bus inversion from a memory controller to the memory core.

11. The apparatus of claim 8, wherein the data bus inversion logic is further to:
arrange bits of the data signal non-sequentially among the TSVs in accordance with the data bus inversion of the data signal.

12. The apparatus of claim 11, wherein the data bus inversion logic comprises:
a multi-entry first-in-first-out buffer to arrange the bits of the data signal non-sequentially.

13. The apparatus of claim 8, wherein the memory core is associated with a plurality of ranks, and wherein the data bus inversion logic is further to:
keep track of previous read cycles for consecutive read operations to different ranks of the plurality of ranks.

14. The apparatus of claim 13, wherein the data bus inversion logic is further to:
keep track of data sent from an inactive rank of the plurality of ranks.

15. An electronic apparatus, comprising:
an interposer
a processor coupled to the interposer; and
at least one memory stack device coupled to the interposer and communicatively coupled to the processor through the interposer, the at least one memory stack device including a stack of dice including at least one logic die and at least two memory dice, wherein the at least one logic die and the at least two memory dice are coupled to each other by a plurality of through-silicon-vias (TSVs), and wherein the at least two memory dice each comprise data bus inversion logic to:
encode and decode a data signal on a signal path through the TSVs in accordance with a data bus inversion of the data signal.

16. The apparatus of claim 15, wherein the data bus inversion logic is further to:
extend the data bus inversion from the processor to the at least two memory dice.

17. The apparatus of claim 15, wherein the data bus inversion logic is further to:
arrange bits of the data signal non-sequentially among the TSVs in accordance with the data bus inversion of the data signal.

18. The apparatus of claim 17, wherein the data bus inversion logic comprises:
a multi-entry first-in-first-out buffer to arrange the bits of the data signal non-sequentially.

19. The apparatus of claim 15, wherein the at least one memory stack device is associated with a plurality of ranks, and wherein the data bus inversion logic is further to:
keep track of previous read cycles for consecutive read operations to different ranks of the plurality of ranks.

20. The apparatus of claim 19, wherein the data bus inversion logic is further to:
keep track of data sent from an inactive rank of the plurality of ranks.
